(19) United States
(12) Patent Application Publication
(10) Pub. No.: US 2002/0180014 A1
(43) Pub. Date: Dec. 5, 2002

(54) Enhanced performance surface mount semiconductor package devices and methods

(76) Inventor: Kenneth R. Philpot, Nashua, NH (US)

Correspondence Address: Arthur I. Navarro, NAVARRRO IP LAW GROUP, Suite 655, 801 E. Campbell Rd., Richardson, TX, 75081, US

(21) Appl. No.: 09/873,059

(22) Filed: Jun. 2, 2001

(51) Int. Cl. H01L 23/02

(52) U.S. Cl. 257/678

(57) ABSTRACT

A surface mount semiconductor device package and method is disclosed. The surface mount semiconductor device package is compact and minimizes the length of bond wires in order to minimize series inductance. The encapsulant material is of low dielectric constant in order to minimize parasitic capacitance. The substrate material is selected to improve heat transfer characteristics. The features of the invention offer increased high frequency performance.

### TECHNICAL FIELD

The present invention relates to surface mount packaging for semiconductor devices. More specifically, the invention relates to semiconductor package design and materials that extend the useful frequencies of operation and provide improved heat dissipation and electrical characteristics.

### BACKGROUND OF THE INVENTION

Commonly, semiconductor devices are mounted on a plastic encapsulated lead frame. The package includes leads and pins for making electrical connections between the packaged device and a larger component, typically a circuit board. In this arrangement bonding wires, leads and pins add undesirable series inductance to the electrical characteristics of the packaged device, often severely degrading performance, especially at high frequencies.

An additional problem with conventional semiconductor device packages is the introduction of parasitic capacitance due to the dielectric properties of the encapsulation materials. A related problem with standard semiconductor packaging is that the dielectric properties of the encapsulating material can vary from device to device, often rendering the precise characteristics of individually packaged devices inconsistent in performance.

Standard packages also often suffer from problems with heat dissipation. One of the basic limitations of semiconductor devices is the necessity to dissipate heat generated during operation. Heat must be transferred elsewhere to avoid excessive increases in temperature within the device itself. Commonly, heat dissipation is thwarted by the necessity for solder pins which place physical limitations on the attachment of the typical semiconductor package to a circuit board. Additionally, common packaging and substrate materials typically have limited thermal conductivity, which can be detrimental to performance. Some device packages in the art also have a problem with the separation of substrate and resin due to repeated expansion and contraction.

The problems with conventional surface-mount semiconductor device packaging are particularly acute in high frequency applications. As a result, microwave telecommunications devices, operating at frequencies greater than 1.0 GHz, are particularly affected.

Due to problems with current surface mount semiconductor packaging technology, including those problems identified above, a need exists for a semiconductor package and method that improves thermal properties and reduces series inductance and parasitic capacitance improving performance, particularly at higher operating frequencies.

### SUMMARY OF THE INVENTION

In general, the invention provides apparatus and methods for packaging one or more semiconductor devices in a surface mount assembly with improved electrical and thermal properties. The improved device package uses a thermally conductive substrate having one or more planar surfaces. A semiconductor device is mounted on a surface of the substrate and encapsulated in a low dielectric constant encapsulating material that has thermal expansion properties similar to those of the substrate. The choice of encapsulant reduces parasitic capacitance. Lead lengths are minimized to reduce series inductance. Pins are eliminated to further reduce series inductance and improve heat dissipation.

According to one aspect of the invention, a planar ceramic substrate has a semiconductor device mounted on one surface. Conductive pads are mounted on the opposite surface of the substrate, and inductance-minimized conductive leads bond the semiconductor device to the conductive pads. A material having a low dielectric constant encapsulates the semiconductor device and adjoining substrate surface.

According to another aspect of the invention, a method of manufacturing a surface mount semiconductor device package includes affixing a semiconductor device to the surface of a ceramic substrate. Conductive pads are affixed to the opposing surface of the substrate. The semiconductor device and conductive pads are electrically bonded with low-inductance conductive leads. The semiconductor device is also encapsulated in a low dielectric constant material.

Several advantages will become apparent in the description of the apparatus and method of the invention. The low dielectric constant of the encapsulant material acts to reduce parasitic capacitance. Carefully controlling the length of the conductive leads minimizes series inductance. The selection of substrate material having good thermal conductivity characteristics provides improved heat transfer characteristics for semiconductor device packages using the invention. As a result of the above advantages, singly and in combination, the semiconductor device package operates with improved performance, particularly at microwave frequencies.

### BRIEF DESCRIPTION OF THE DRAWINGS

For a better understanding of the invention including its features, advantages and specific examples of preferred embodiments, reference is made to the following detailed description along with accompanying drawings in which:

FIG. 1 is a cut away side view of the semiconductor device package of the invention;

FIG. 2 is a top view of the apparatus of FIG. 1;

FIG. 3 is a bottom view of the apparatus of FIG. 1;

FIG. 4 is a top perspective view of an example of apparatus, according to the invention providing a multiple-device package; and

FIG. 5 is a process flow diagram illustrating the steps in the method of manufacturing the apparatus of FIGS. 1-4.

References in the detailed description correspond to like references in the figures unless otherwise noted.

### DETAILED DESCRIPTION OF PREFERRED EMBODIMENTS

While the making and using of various embodiments of the present invention are discussed in detail below, it should be appreciated that the present invention provides many applicable inventive concepts which can be embodied in a wide variety of specific contexts. It should be understood that the invention may be practiced with various numbers of semiconductor devices of various materials and configurations. Some features of embodiments shown and discussed are simplified or exaggerated for illustrating the principles of the invention.

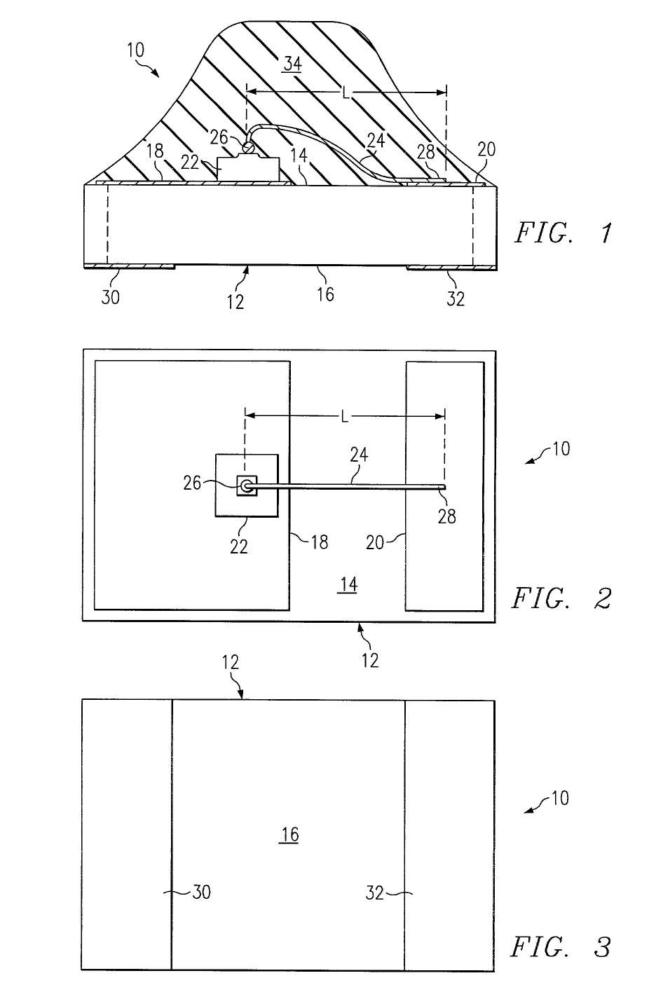

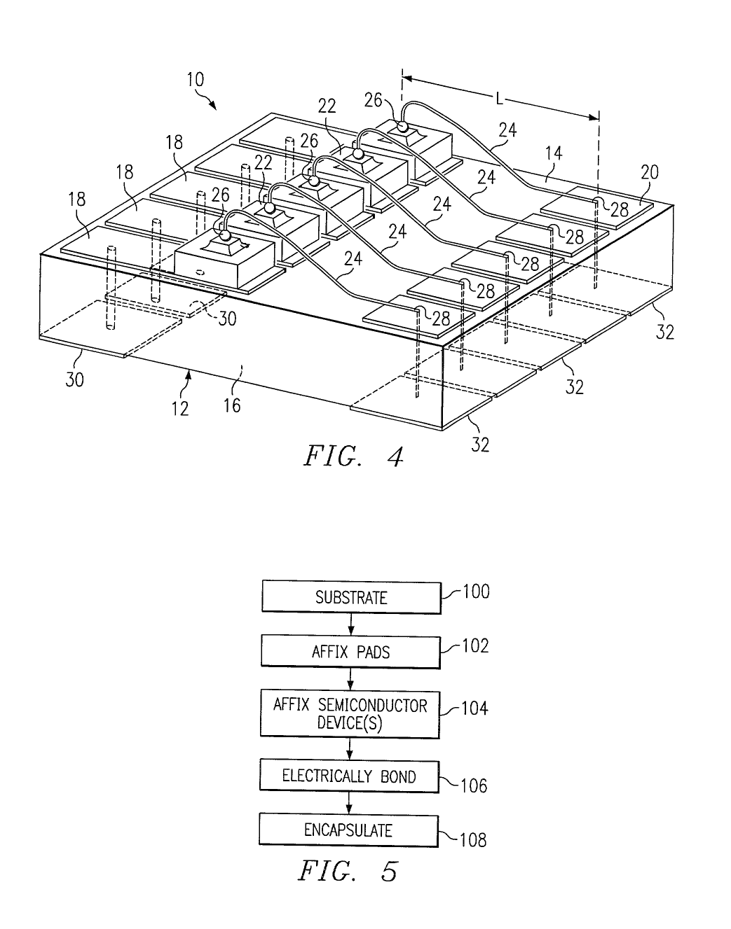

A preferred embodiment of the invention is illustrated in FIGS. 1-3. An implementation of the invention incorporating a single semiconductor device is shown. It should be clear that the concept of the invention is equally applicable to packaging more complex semiconductor devices and multiple semiconductor devices in a single package. Those skilled in the arts will also appreciate that, in general, devices used in narrow-range frequency applications can achieve higher frequency operation than in applications requiring a broader range of frequencies.

The package 10 is shown with a substrate 12, preferably made primarily of alumina (Al₂O₃), although beryllia (BeO) or other ceramic materials may also be used. It is important that the substrate material have relatively high thermal conductivity. Typically the package has a thermal resistance of less than 200 degrees Centigrade per Watt, preferably less than 50 degrees Centigrade per Watt. It is believed that some application packages according to the invention will have an overall thermal resistance of approximately 25 degrees Centigrade per Watt. The substrate 12 has a first surface 14 and an opposing second surface 16. Leads 18, 20 are provided on the first surface 14 for making electrical connections to a semiconductor device 22. Although a two-terminal device is shown, it will be understood that various devices will require various numbers of connections. The semiconductor device 22 is mounted on the first surface 14 of the substrate 12 such that it makes electrical contact at the appropriate points, according to the configuration of the semiconductor device 22, with the mounting lead 18. A wire 24 is typically bonded at its ends 26, 28 to the semiconductor device 22 and an opposing lead 20. The leads 18, 20 are electrically bonded to corresponding conductive pads 30, 32. Thus, electrical paths appropriate for the operation of the particular semiconductor device 22 are provided between the semiconductor device 22 and the second surface 16 of the substrate 12. The leads 18, 20, bond wire 24, and pads 30 are preferably gold, although other conductive metals such as platinum or aluminum may be used. The length L of the wire 24 is carefully controlled so that undesirable series inductance characteristics can be limited. Typically, it is preferred that series inductance is minimized.

An encapsulant 34 is employed to encapsulate the semiconductor device 22, wire 24, first surface 14, and leads 18, 20. The encapsulant 34 has a low dielectric constant. Typically, the encapsulant 34 is an epoxy resin, preferably one sold under the name FP4451, available from Dexter Corporation. Other materials may be used, provided that a low dielectric constant is provided. Additionally, it is important that the encapsulant 34 and substrate 12 possess similar expansion characteristics, typically given a coefficient of expansion, such that the substrate 12 and encapsulant 34 do not become separated by repeated cycles of heating and cooling.

It should be understood that the package apparatus and methods of the invention may be practiced with surface mount packages independent of the size or style of package. For example, in order to provide compatibility with existing designs, the invention may be practiced to produce package styles known in the art, such as a Standard Outline Transistor 23 (SOT-23) or a Standard Outline Diode 323 (SOD-323). Of course, package configurations adapted to accommodate particular devices may also be devised. The invention may be practiced with various types of devices, for example, Schottky diodes, bipolar transistors, tuning varactors, limiters, pin switches, and pin attenuators, to name a few. It is anticipated that the invention will be particularly advantageous for use with microwave semiconductor devices, particularly devices operating in the frequency range from about 2-12 GHz.

An example of an embodiment of the invention having multiple semiconductor devices 22 in a single package 10 is shown in FIG. 4. As shown and described with reference to FIGS. 1-3, an encapsulant 34 is employed to encapsulate multiple semiconductor devices 22, wires 24, leads 18, 20 and first surface 14 of the substrate 12. As in the previously described embodiment, the materials and configuration are chosen to minimize series inductance and parasitic capacitance, and maximize heat transfer characteristics yielding improved performance, particularly at microwave frequencies.

FIG. 5 is a process flow diagram showing the steps of assembling a semiconductor package according to the invention. Beginning with a substrate 100 of suitable material, such as alumina, conductive pads, preferably gold, are affixed to a substrate surface in step 102. In step 104, one or more semiconductor devices are affixed to the opposing surface of the substrate. Common methods or adhesives may be used in steps 102 and 104. In step 106, the appropriate terminals of the devices are electrically bonded to the conductive pads of the substrate. The devices and preferably the adjoining surface of the substrate are encapsulated, in step 108, in low-dielectric encapsulant material. Various techniques known in the manufacturing arts may be used to accomplish the steps shown in FIG. 5. Of course, automated processes may be used which may introduce additional techniques such as, for example, separating finished devices after encapsulation. It should be clear from the foregoing descriptions with reference to FIGS. 1-4 that it is essential that the substrate be selected for its thermal conductivity properties. It should be equally clear that the step of electrically coupling 106 the device and conductive pads should include carefully controlling the length of the necessary wires and leads as much as possible within the limitations imposed by the physical requirements of the device. Additionally, it should be understood that the encapsulant should be selected for providing both a relatively uniformly distributed low dielectric constant, and a thermal expansion coefficient similar to that of the substrate.

The embodiments shown and described above are only exemplary. Even though numerous characteristics and advantages of the present invention have been set forth in the foregoing description together with details of the method of the invention. Physical variations such as the number of chips, devices, number of terminal connections, package footprint, and number of bond wires affect the series inductance and shunt capacitance, but do not affect the implementation of the concepts of the invention. The disclosure is illustrative only and changes may be made within the principles of the invention to the full extent indicated by the broad general meaning of the terms used in the attached claims.

We claim:

1. A surface-mount semiconductor device package comprising:
a substrate having at least one planar surface;
a semiconductor device disposed on the planar surface of the substrate; and
an encapsulant surrounding the semiconductor device wherein the encapsulant material has thermal expansion properties substantially similar to the thermal expansion properties of the substrate.

2. A surface-mount semiconductor device package according to claim 1 wherein the package thermal resistance is less than about 200 degrees Centigrade per Watt.

3. A surface-mount semiconductor device package according to claim 1 wherein the package thermal resistance is less than about 50 degrees Centigrade per Watt.

4. A surface-mount semiconductor device package according to claim 1 wherein the package thermal resistance is less than approximately 25 degrees Centigrade per Watt.

3. A surface-mount semiconductor device package according to claim 1 further comprising a plurality of conductive pads disposed on a surface of the substrate and electrically bonded to the semiconductor device.

4. A surface-mount semiconductor device package according to claim 3 further comprising conductive leads for electrically coupling the conductive pads to the semiconductor device.

5. A surface-mount semiconductor device package according to claim 1 wherein the substrate comprises ceramic material.

6. A surface-mount semiconductor device package according to claim 1 wherein the substrate comprises alumina.

7. A surface-mount semiconductor device package according to claim 1 wherein the substrate comprises beryllia.

8. A surface-mount semiconductor device package according to claim 1 wherein the encapsulant material comprises epoxy resin.

9. A surface-mount semiconductor device package according to claim 1 wherein the encapsulant material comprises Dexter FP4451 epoxy resin.

10. A surface-mount semiconductor device package according to claim 1 wherein the semiconductor device is operable at frequencies within a range of about 2-10 GHz.

11. A surface-mount semiconductor device package according to claim 1 wherein the semiconductor device is operable at frequencies within a range of about 10-12 GHz.

12. A surface-mount semiconductor device package comprising:
a planar ceramic substrate having a first surface and an opposing second surface;
a semiconductor device disposed on the substrate first surface;
conductive pads disposed on the substrate second surface;
conductive leads coupling the semiconductor device to the conductive pads; and
a low dielectric constant encapsulant material encapsulating the semiconductor device and substrate first surface.

13. A surface-mount semiconductor device package according to claim 12 wherein the substrate comprises alumina.

14. A surface-mount semiconductor device package according to claim 12 wherein the substrate comprises beryllia.

15. A surface-mount semiconductor device package according to claim 12 wherein the encapsulant material comprises epoxy resin.

16. A surface-mount semiconductor device package according to claim 12 wherein the encapsulant material comprises Dexter FP4451 epoxy resin.

17. A surface-mount semiconductor device package according to claim 12 wherein the semiconductor device is operable at frequencies within a range of about 2-10 GHz.

18. A surface-mount semiconductor device package according to claim 12 wherein the semiconductor device is operable at frequencies within a range of about 10-12 GHz.

19. A method of manufacturing a surface-mount semiconductor device package comprising:
affixing a semiconductor device to a first surface of a ceramic substrate;
affixing conductive pads to an opposing second substrate surface;
coupling the semiconductor device to the conductive pads with conductive leads; and
encapsulating the semiconductor device in a low dielectric constant encapsulant material.

20. A method of manufacturing a surface-mount semiconductor device package according to claim 19 wherein the step of coupling the semiconductor device to the conductive pads further comprises the step of selecting the length of the conductive leads such that the series inductance of the device package is minimized.

21. A method of manufacturing a surface-mount semiconductor device package according to claim 19 wherein the step of encapsulating the semiconductor device further comprises the step of selecting an encapsulant material such that the parasitic capacitance of the device package is minimized.
